(19) United States
(12) Patent Application Publication
(10) Pub. No.: US 2026/0043834 A1
(43) Pub. Date: Feb. 12, 2026

(54) Electrical Current Measurement Module

(71) Applicant: Schneider Electric Industries SAS, Rueil Malmaison (FR)

(72) Inventors: Juliette KOCH, Grenoble (FR); Sebastien BUFFAT, Tullins (FR)

(21) Appl. No.: 19/282,415

(22) Filed: Jul. 28, 2025

(30) Foreign Application Priority Data
Aug. 7, 2024 (FR) FR2408750

(51) Int. Cl. G01R 15/18; G01R 19/00

(52) U.S. Cl. CPC G01R 15/181; G01R 19/0092

(57) ABSTRACT

The present invention relates to an electrical current measurement module (1) for measuring an electrical current passing through an electrical conductor (3). The measurement module comprises at least one ferromagnetic element (23) and two identical rectilinear portions (6) of a main coil (7) of electrically conductive wire (9). Each rectilinear portion includes a support (11) comprising a body (13) of linear shape and at least one end (15). The measurement module is configured to adopt a closed configuration in which the at least one ferromagnetic element covers the distinct end of each rectilinear portion of the main coil, and an open configuration in which the at least one ferromagnetic element is separated from the rectilinear portions.

### FIELD

The present invention relates to an electrical current measurement module.

The invention pertains to the field of devices for measuring electrical magnitudes.

### BACKGROUND

Electrical installations, such as local electricity distribution networks, used for distributing electricity within a building, usually include several loads and, where applicable, several sources, connected by electrical conductors.

There is a need to ensure the supervision, proper operation and safety of such electrical installations and, to this end, it is useful to provide means of measuring electrical magnitudes enabling the electrical signals circulating in the electrical conductors to be characterized by measuring electrical magnitudes.

In particular, current measurement ensures safety by enabling protection devices such as circuit breakers to be tripped.

Thus, the implementation of current measuring devices is a recurring problem in the field of supervision of electrical installations.

In the field of current measuring devices, in particular for measuring alternating current or current pulses, there are known devices that use a helical coil of conductive wire, also called a winding, referred to as “Rogowski sensors”. The coil is preferably circular in shape, forming a ring inside which the electrical conductor carrying the electrical current to be measured is positioned. The voltage induced in the coil is proportional to the rate of change, i.e. the time derivative, of the current flowing through the conductor. The circular shape of the coil, with equidistant turns, has the best properties from a theoretical point of view, but is difficult to achieve in practice.

In variants, the current sensor is formed from several linear coils, arranged for example in a square and delimiting a central space for the electrical conductor to pass through. However, in such an arrangement it is difficult to guarantee the immunity of the sensor to current sources other than the electrical conductor carrying the current to be measured. Conventionally, additional turns are placed in the corners of such a current sensor to capture the flux in the corners.

There are opening Rogowski sensors with coils on a flexible armature, which makes it easier to insert the electrical conductor centred between the sensor coils, without having to disconnect the electrical conductor. This has the advantage of making the installation of such sensors easier and less time-consuming.

However, known sensors of this type are not very compact, their overall size preventing them from being integrated into small electrical panels.

### SUMMARY

The object of the invention is therefore to overcome these drawbacks by providing a compact, robust, opening electrical current measurement module that provides high performance, while being easy to manufacture.

To this end, the invention relates to an electrical current measurement module for measuring an electrical current passing through an electrical conductor, the measurement module comprising:
two identical rectilinear portions of a main coil of electrically conductive wire, each rectilinear portion including a support comprising a body of linear shape and at least one end,
at least one ferromagnetic element.

According to the invention, the measurement module is configured to adopt
a closed configuration in which the at least one ferromagnetic element covers the distinct end of each rectilinear portion of the main coil, and
an open configuration in which the at least one ferromagnetic element is separated from the rectilinear portions.

The invention, notably on account of the two rectilinear portions of the main coil of conductive wire and the ferromagnetic elements, provides a measurement module that can be opened and is simple to manufacture. Moreover, the presence of identical rectilinear portions ensures good robustness and good performance of the measurement module.

According to other advantageous aspects of the invention, the electrical current measurement module comprises one or more of the following features, taken alone or in any technically possible combinations:
The rectilinear portions of the main coil have identical and constant linear densities of electrically conductive wire over their respective length.
For each rectilinear portion, a beginning of the coil of conductive wire and an end of the coil of conductive wire are positioned at the at least one end.
For each rectilinear portion, a maximum transverse dimension of the at least one end is greater than a maximum transverse dimension of the body.
The rectilinear portions are made of printed circuit.
The at least one ferromagnetic element comprises two housings shaped to fit the ends so that the ends are housed and centred in the housings in the closed configuration.
Each of the housings is formed by an end portion of the at least one ferromagnetic element which defines at least one air gap passing through a peripheral wall of the housing to the outside of the housing.
The at least one ferromagnetic element is made by folding a plate of ferromagnetic material.
The plate comprises a central rectilinear portion and two pairs of tabs extending at ends of the rectilinear portion, each pair of tabs forming one of the housings once the plate is folded.
The measurement module comprises at least one additional ferromagnetic-element plate fastened to the at least one ferromagnetic element.
The at least one ferromagnetic element is made by machining.
The at least one ferromagnetic element is made of a ferromagnetic material having a relative magnetic permeability greater than or equal to 10,000.
The measurement module comprises two ferromagnetic elements.
The measurement module comprises a single ferromagnetic element.

The invention will become more clearly apparent upon reading the following description, given solely by way of non-limiting example and with reference to the drawings, in which:

### BRIEF DESCRIPTION OF DRAWINGS

FIG. 1 is a perspective view of a measurement module according to a first embodiment of the invention and of an associated electrical conductor,

FIG. 2 is an exploded perspective view of the measurement module in FIG. 1,

FIG. 3 is a perspective view of a main coil of conductive wire belonging to the measurement module in FIG. 1,

FIG. 4 is a plan view of a ferromagnetic element belonging to the measurement module in FIG. 1, before being shaped,

FIG. 5 is a perspective view, similar to FIG. 1 but without an associated electrical conductor, of a measurement module according to a second embodiment of the invention,

FIG. 6 is a perspective view, similar to FIG. 5, of a measurement module according to a third embodiment of the invention,

FIG. 7 is a perspective view, similar to FIG. 1 but without an associated electrical conductor, of a measurement module according to a fourth embodiment of the invention, and

FIG. 8 is a perspective view, similar to FIG. 1 but without an associated electrical conductor, of a measurement module according to a fifth embodiment of the invention.

### DETAILED DESCRIPTION

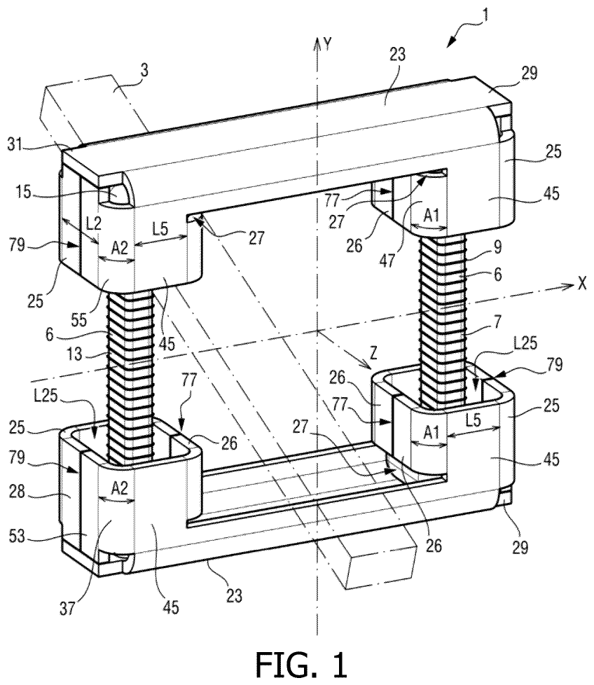

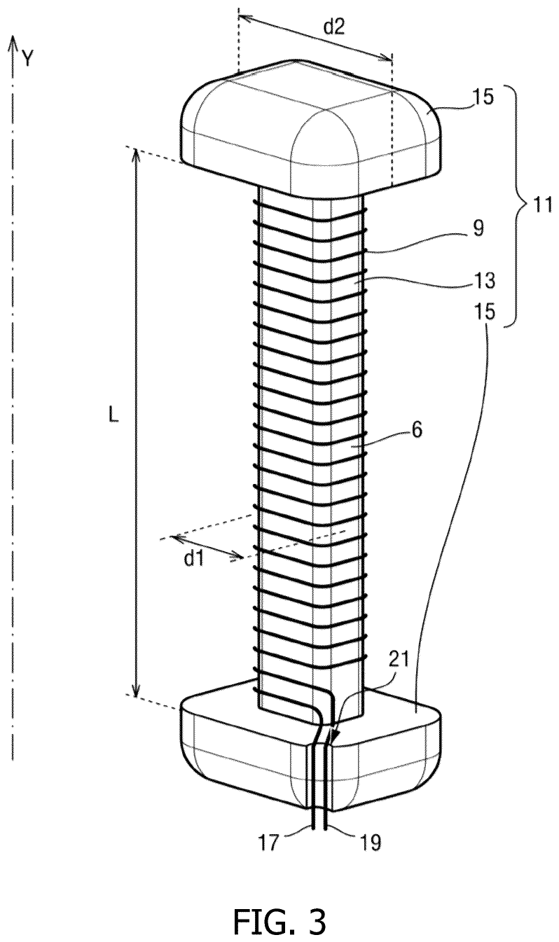

An electrical current measurement module 1 according to a first embodiment is shown in FIGS. 1 to 5.

The current measurement module 1 is intended to continuously measure an electrical current passing through an electrical conductor 3.

The electrical conductor 3 forms part of an electrical installation, not shown, in which the measurement module 1 can be positioned to measure the current.

The measurement module 1 is an inductive current sensor including a main coil 7 of electrically conductive wire 9, also called the main winding.

In this example, the main coil 7 comprises two distinct rectilinear portions 6 that are independent of each other. The two rectilinear portions 6 are identical to each other. Each rectilinear portion 6 includes a support 11 of linear shape. Each support 11 comprises a body 13 and at least one end 15, in this example the support comprises two ends 15 arranged at the two ends of the body 13.

Each body 13 is of linear shape and extends parallel to a longitudinal axis Y defined by the measurement module 1. Each body 13 has a section perpendicular to the axis Y which is constant, for example rectangular. A maximum transverse dimension of the section of the body 13 is denoted d1.

The ends 15 are for example rectangular. A maximum transverse dimension of the ends 15 is denoted d2.

Advantageously, the maximum transverse dimension d2 of the ends 15 is strictly greater than the maximum transverse dimension d1 of the section of the body 13.

The main coil 7 is made by helically winding a wire 9 around each support 11. In particular, the wire 9 is at least wound around the body 13 over a length L measured between the two ends 15 from a beginning 17 of the coil of wire 9 to an end 19 of the coil of wire 9. In this example, the beginning 17 and the end 19 of the coil are advantageously positioned on the same end 15 of the support 11.

The wire 9 is for example a copper wire, the support 11 being made of synthetic material, notably of plastics material, for example liquid crystal polymer (LCP).

Advantageously, for each rectilinear portion 6, the beginning 17 and the end 19 of the coil are positioned on one side of the same end 15.

Advantageously, one end 15 of each rectilinear portion 6 comprises a first slot 21 arranged in such a way that the beginning 17 and the end 19 of the coil pass through and are wedged in the first slot 21, thus ensuring that the coil of wire 9 is held in place on the support 11.

Advantageously, the rectilinear portions 6 have identical and constant linear densities of wire 9 over their respective length L, the linear densities being between 40 turns per millimetre and 80 turns per millimetre.

The measurement module 1 further includes at least one ferromagnetic element 23. In this example, the measurement module 1 comprises two ferromagnetic elements 23.

XYZ denotes an orthogonal coordinate system associated with the assembled measurement module 1, in which the X-axis is parallel to a longitudinal direction of the ferromagnetic elements 23, the Y-axis is parallel to a longitudinal direction of the rectilinear portions 6 and the Z-axis is parallel to a direction in which the electrical conductor 3 passes through the measurement module 1.

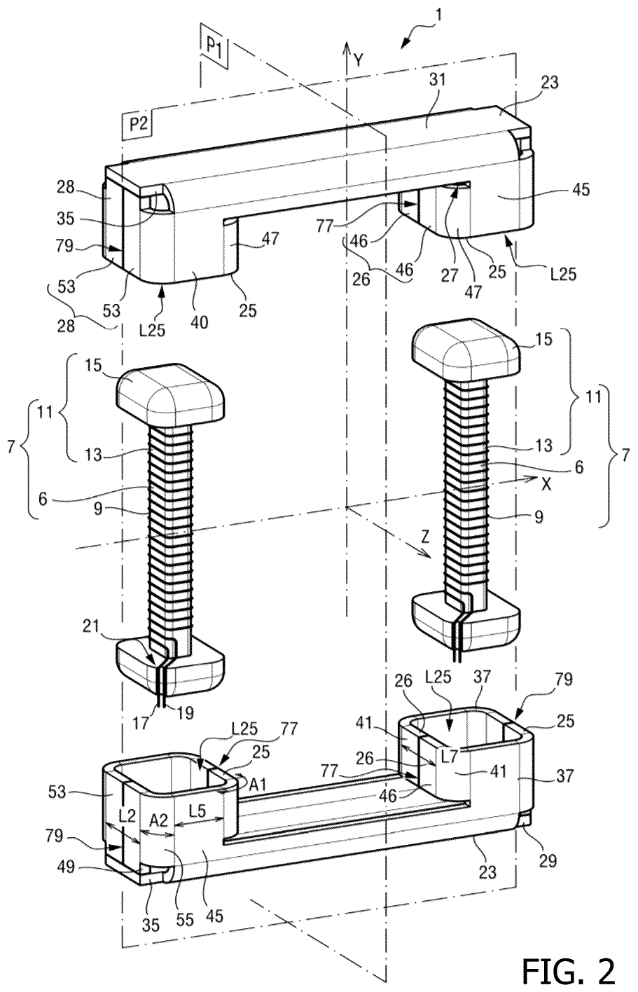

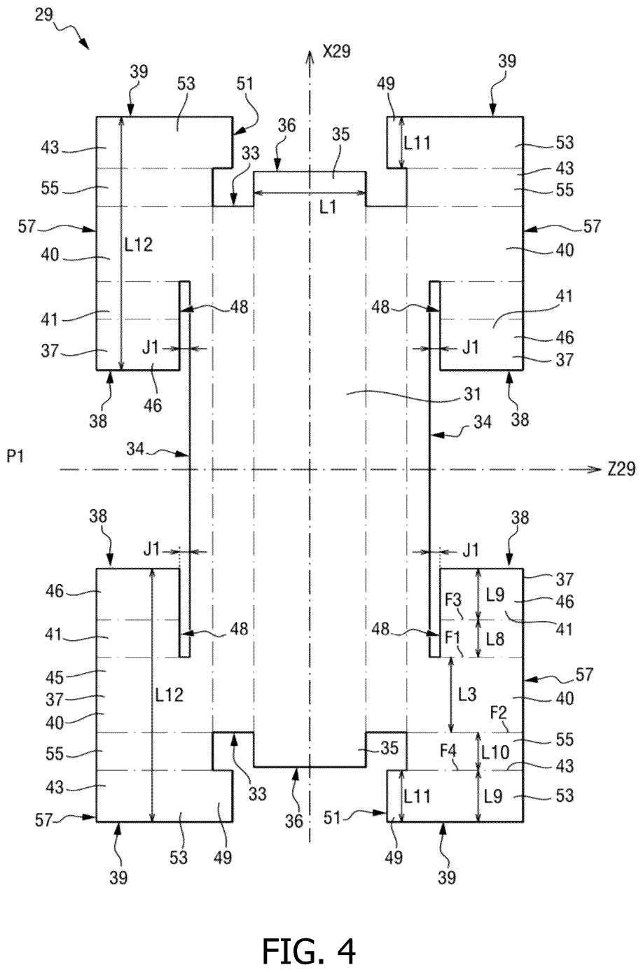

The ferromagnetic elements 23 extend transversely to the electrical conductor 3, parallel to the axis X which is perpendicular to the axis Y. The ferromagnetic elements 23 are symmetrical with respect to a first plane of symmetry P1 normal to the transverse axis X and visible in FIGS. 2 and 4.

Each ferromagnetic element 23 comprises two end portions 25 each defining a housing L25. Each housing L25 extends parallel to the longitudinal axis Y when the measurement module 2 is assembled.

Advantageously, each housing L25 is shaped to fit the ends 15.

Reference sign 26 denotes an inner peripheral wall of an end portion 25 turned towards the other end portion 25 of the same ferromagnetic element 23. Advantageously, each end portion 25 comprises a second slot 27 on its inner wall 26. The second slot 27 extends perpendicularly to the axes X and Y when the measurement module 1 is assembled. The second slot 27 passes through the inner wall 26 and opens to the outside of the housing L25, connecting the housing L25 to the outside.

For each ferromagnetic element 23, the second slots 27 are facing each other. In other words, the inner wall 26 is the wall of a housing L25 normal to the transverse axis X and positioned at the shortest distance from a wall normal to the transverse axis X of the other housing L25 of the ferromagnetic element 23.

Reference sign 28 denotes an outer peripheral wall of an end portion 25 turned away from the other end portion 25 of the same ferromagnetic element 23, the outer wall 28 being the second wall of the end portion 25 normal to the axis X.

Advantageously, the ferromagnetic elements 23 are made of ferromagnetic materials having a relative magnetic permeability greater than or equal to 10,000. The relative magnetic permeability of a material means the ratio of its magnetic permeability to the magnetic permeability of a vacuum. For example, the ferromagnetic elements 23 are made of steel, and more precisely of an iron-nickel or iron-silicon alloy, these materials having a high magnetic permeability.

Advantageously, each ferromagnetic element 23 is made by folding a plate 29, shown unfolded in FIG. 4.

The plate 29 comprises a rectilinear portion 31 extending along a transverse axis X29 parallel to the axis X once the ferromagnetic element 23 has been folded and mounted in the measurement module 1 of the ferromagnetic element 23. The rectilinear portion 31 comprises two longitudinal edges 33 extending perpendicularly to the transverse axis X29 and two identical transverse edges 34 extending parallel to the transverse axis X29.

The plate 29 also comprises, on each longitudinal edge 33, a protuberance 35 extending parallel to the transverse axis X29 beyond the adjacent longitudinal edge 33 and comprising a central edge 36.

Each central edge 36 is parallel to the longitudinal edges 33 and centred on the transverse axis X29. A length L1 of the central edges 36 is equal to a width L2 of the outer wall 28.

The plate 29 also comprises two pairs of identical tabs 37 extending at the ends of the rectilinear portion 31. More precisely, the tabs 37 extend the four corners of the rectilinear portion 31.

The four tabs 37 are identical and extend parallel to the transverse axis X29 between an inner edge 38 and an outer edge 39.

The plate 29 is symmetrical with respect to the transverse axis X29 and symmetrical with respect to an axis of symmetry Z29 perpendicular to the transverse axis X29. Once the ferromagnetic element 23 has been folded and mounted in the measurement module 1, the axis Z29 is parallel to the axis Z.

Each tab 37 comprises a central portion 40, an inner portion 41 and an outer portion 43. The inner portion 41 and the outer portion 43 extend parallel to the transverse axis X29 on each side of the central portion 40.

The central portion 40 is delimited by two fold lines F1 and F2 perpendicular to the transverse axis X29. The fold line F1 separates the central portion 40 from the inner portion 41 and the fold line F2 separates the central portion 40 from the outer portion 43.

When the tab is folded, the central portion 40 forms a middle wall 45 parallel to the transverse axis X29 of an end portion 25, the middle wall 45 connecting the inner wall 26 to the outer wall 28. The fold lines F1 and F2 are spaced apart by a length L3 equal to a length L5 of the middle walls 45.

The inner portion 41 is delimited by the fold line F1 and the inner edge 38. The inner portion 41 also comprises a fold line F3 perpendicular to the transverse axis X29. The inner edge 38 and the fold line F3 are spaced apart by a length L6 equal to half a length L7 of the inner wall 26. The fold lines F1 and F3 are spaced apart by a length L8 equal to an arc length A1 of the inner corners 47 connecting one of the middle walls 45 to the inner wall 26 of the housing L25.

When the tab 37 is folded, the inner portion 41 forms the half 46 of the inner wall 26 of the housing L25 and one of the inner corners 47 of the housing L25.

Reference sign 48 denotes a lower inner edge of the inner portion 41, the lower inner edge 48 being the edge of the inner portion 41 at the shortest distance from one of the transverse edges 34.

The plate 29 defines, for each tab 37, a clearance J1 of non-zero thickness between the lower inner edge 48 and the closest transverse edge 34. The clearance J1 forms the second slot 27 when the tabs 37 are folded to form the housings L25.

The outer portion 43 is delimited by the fold line F2 and the outer edge 39. The outer portion 43 also comprises a fold line F4 perpendicular to the transverse axis X29. The outer edge 39 and the fold line F4 are spaced apart by a length L9 equal to half the length L2 of the outer wall 28. The fold lines F2 and F4 are spaced apart by a length L10 equal to an arc length A2 of the outer corners 55 connecting one of the middle walls 45 to the outer wall 28 of the housing L25.

The outer portion 43 comprises an extension 49 which extends perpendicularly to the transverse axis X29 towards the transverse axis X29. The extension forms a lower outer edge 51. A length L11 of the lower outer edge 51 is equal to half the length L1 of the central edges 36.

When the tab 37 is folded, the outer portion 43 forms a half 53 of the outer wall 28 of the housing L25 and one of the outer corners 55.

Reference sign 57 denotes an upper edge of a tab 37, the upper edge 57 being the edge parallel to the transverse axis X29 at the greatest distance from the transverse edges 34. The upper edge 57 is also an edge common to the central portion 40, the inner portion 41 and the outer portion 43. A length L12 of the upper edge 57 is equal to the sum of the lengths L3, L6, L8, L9 and L10. In other words, the length L1 is equal to the sum of the length L5 of the middle walls 45, half the length L1, half the length L7, the arc length A1 of the inner corners 47 and the arc length A2 of the outer corners 55.

When two tabs 37 symmetrical with respect to the transverse axis X29 are folded to form a housing L25, the inner edges 38 are arranged to face each other so that the inner portions 41 form the inner peripheral wall 26 and the outer edges 39 are arranged to face each other so that the outer portions 43 form the outer peripheral wall 28. The lower outer edges 51 are then in contact with the central edge 36.

Once the tabs are in the folded configuration, the inner edges 38 are not in contact and define, between each other, an internal air gap 77 in the form of a rectilinear slot parallel to the axis Y, which passes through the thickness of the inner peripheral wall 26. In a comparable manner, in this configuration, the outer edges 39 are not in contact and define, between each other, an external air gap 79 in the form of a rectilinear slot parallel to the axis Y, which passes through the thickness of the outer peripheral wall 28.

Each ferromagnetic element 23 thus defines two internal air gaps 77 and two external air gaps 79.

The air gaps 77 and 79 respectively divide the inner peripheral wall 26 and the outer peripheral wall 28 in two. In particular, the housings L25 open to the outside through the peripheral walls 26 and 28, via the air gaps 77 and 79.

The air gaps 77 and 79 prevent parasitic induced currents from forming within the housings L25. The air gaps 77 and 79 therefore improve the performance of the measurement module 1. According to a variant of the invention (not shown), a single air gap 77 or 79 is provided for each housing L25, either on its inner peripheral wall 26 or on its outer peripheral wall 28.

In a variant, the air gaps 77 and 79 are not parallel to the axis Y, but inclined with respect to this axis. They may also be curved, for example S-shaped or W-shaped.

The measurement module 1 defines a closed configuration and an open configuration.

In the closed configuration, an end portion 25 of each ferromagnetic element 23 covers each distinct end 15 of each rectilinear portion 6. In other words, in the closed configuration, one end 15 of each rectilinear portion 6 is housed in one of the housings L25 of one of the ferromagnetic elements 23 and the other end 15 is housed in one of the housings L25 of the other ferromagnetic element 23. In the closed position, the measurement module 1 is symmetrical with respect to a second plane of symmetry P2 comprising the axes X and Y.

The measurement module 1 thus formed is a so-called Rogowski sensor. The measurement module 1 uses the Rogowski principle to measure the current of the electrical conductor 3. In other words, the magnetic field induced by the electrical conductor 3 through the measurement module 1 propagates through the ferromagnetic elements 23 and the rectilinear portions 6 of the main coil 7. The current flowing through the electrical conductor can be determined by measuring the voltage at the beginning 17 and at the end 19 of the rectilinear portions 6.

In the open configuration, at least one of the ferromagnetic elements 23 is separated from the main coils.

The measurement module 1 is thus arranged in several portions, so as to allow opening and subsequent closing, thereby making it easier to position the measurement module 1 around the electrical conductor 3.

In other words, the measurement module 1 is an opening sensor formed of several separable portions 7 and 23, allowing the sensor to be opened and closed around the electrical conductor 3.

The constant and identical linear densities of the rectilinear portions 6 preserve the performance of the measurement module 1 during opening and closing since the gain of the measurement module 1 is proportional to the linear density and not to the distance separating the ferromagnetic elements 23.

Moreover, covering the ends 15 of the rectilinear portions 6 with the ferromagnetic elements 23 in the closed configuration enables the winding defects at the ends 15 of the rectilinear portions 6 to be disregarded, since the flux induced by the ends 15 is inside the ferromagnetic elements and does not interfere with the measurement.

The presence of the two ferromagnetic elements 23 surrounding the rectilinear portions 6 ensures good performance of the measurement module 1 and contributes to the robustness of the measurement module 1 by limiting crosstalk.

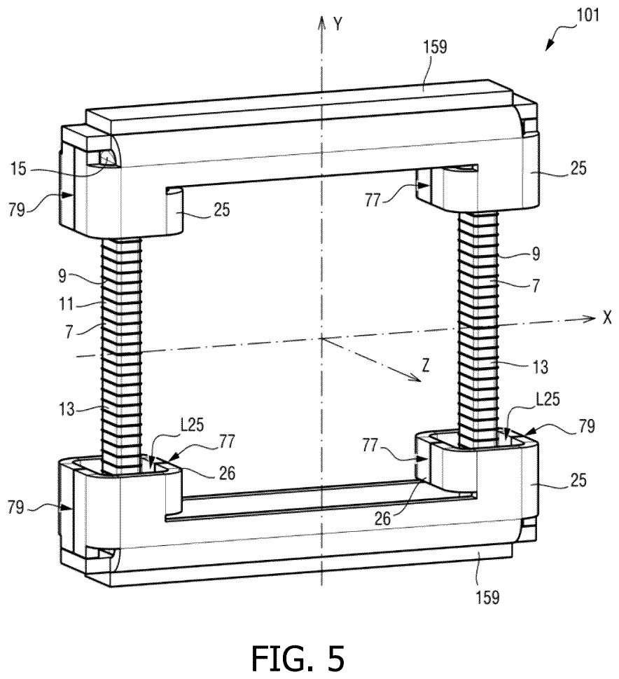

Advantageously, the matching shape of the ends 15 and the housings L25 mechanically centres the ferromagnetic elements 23 with respect to the rectilinear portions 6 so as to ensure a constant gain of the sensor when the sensor is opened and closed. Thus, this facilitates handling by an operator.

Where an element is referenced in one of FIGS. 5 to 8 without being mentioned in the description, it corresponds to the element bearing the same reference in the first embodiment.

A measurement module 101 according to a second embodiment is shown in FIG. 5. The measurement module 101 is identical to the measurement module 1 of the first embodiment, with the exception of the features described below. The reference signs of the measurement module 101 correspond to the reference signs of the measurement module 1 where the reference element is the same. The reference signs are increased by 100 with respect to those of the first embodiment, where they designate elements modified in the measurement module 101.

The measurement module 101 comprises at least one additional plate 159. In this example, the measurement module 101 comprises two additional plates 159. Each additional plate 159 is rectangular and has dimensions identical to the rectilinear portion 31 of the ferromagnetic elements 23. Each additional plate 159 is fastened to one of the ferromagnetic elements 23 on the rectilinear portion 31.

The additional plates 159 raise the magnetic saturation limit of the ferromagnetic elements 23, thereby preventing saturation of the ferromagnetic material.

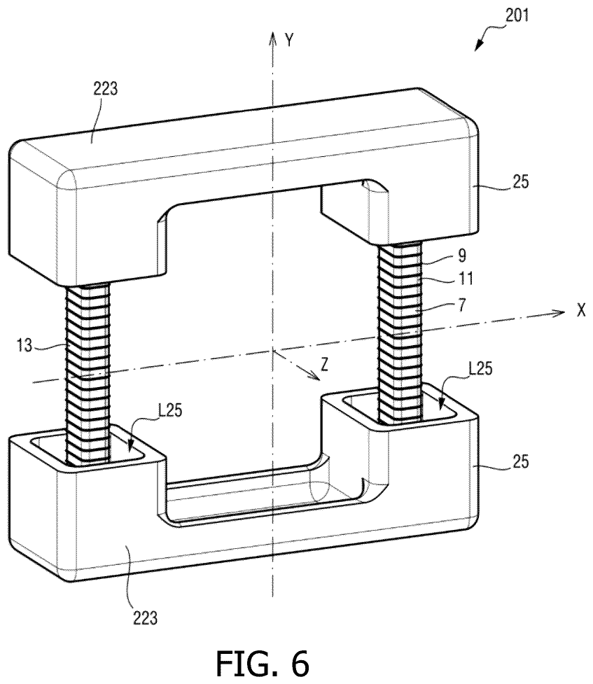

A measurement module 201 according to a third embodiment is shown in FIG. 6. The measurement module 201 is identical to the measurement module 1 of the first embodiment, with the exception of the features described below. The reference signs of the measurement module 201 correspond to the reference signs of the measurement module 1 where the reference element is the same. The reference signs are increased by 200 with respect to those of the first embodiment, where they designate elements modified in the measurement module 201.

The ferromagnetic elements 223 are made by machining. The ferromagnetic elements 223 are mass-produced by a machine tool (not shown) on an automated production line from a ferromagnetic-element block. This makes it easy and inexpensive to manufacture the ferromagnetic elements 223.

In a variant (not shown) of this embodiment, one or more air gaps may be machined in the walls of the housings L25, these air gaps being comparable to the air gaps 77 and 79 of the first embodiment.

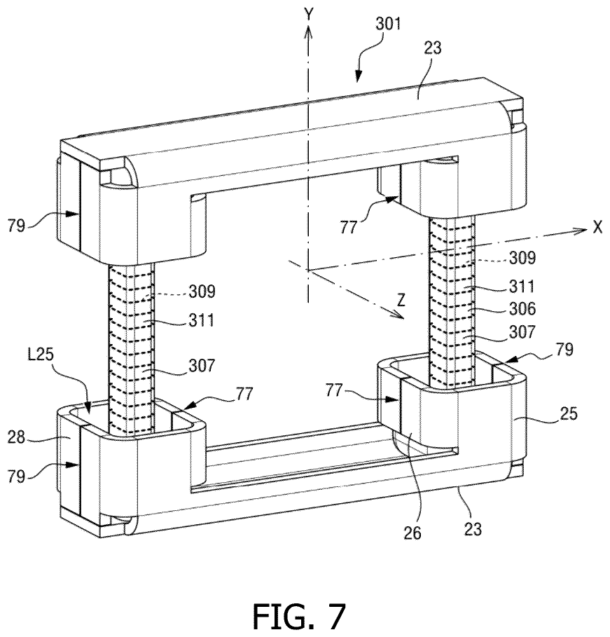

A measurement module 301 according to a fourth embodiment is shown in FIG. 7. The measurement module 301 is identical to the measurement module 1 of the first embodiment, with the exception of the features described below. The reference signs of the measurement module 301 correspond to the reference signs of the measurement module 1 where the reference element is the same. The reference signs are increased by 300 with respect to those of the first embodiment, where they designate elements modified in the measurement module 301.

The rectilinear portions 306 of the measurement module 301 are made in the form of a printed circuit. In other words, each rectilinear portion 306 comprises a support 311 on which an electric wire 309 is directly printed.

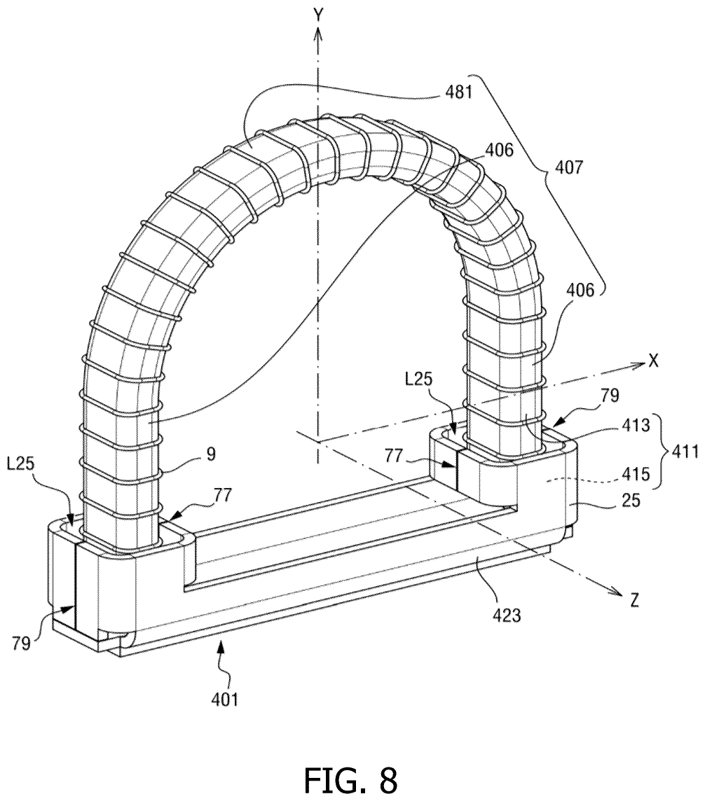

A measurement module 401 according to a fifth embodiment is shown in FIG. 8. The measurement module 401 is identical to the measurement module 1 of the first embodiment, with the exception of the features described below. The reference signs of the measurement module 401 correspond to the reference signs of the measurement module 1 where the reference element is the same. The reference signs are increased by 400 with respect to those of the first embodiment, where they designate elements modified in the measurement module 401.

The measurement module 401 comprises a single ferromagnetic element 423.

The measurement module 401 comprises a main coil 407. The main coil 407 is U-shaped in FIG. 8 and includes a rounded central portion 481 and two rectilinear portions 406 symmetrically extending the rounded central portion 481. Thus, the two rectilinear portions 406 are manufactured from a single piece. Each rectilinear portion 406 includes a support 411 comprising a body 413 of linear shape and one end 415.

The end 15 of each rectilinear portion 406 can be received in one of the housings L25 of the ferromagnetic element 423.

The main coil 407 is made by helically winding a wire 9 around the rounded central portion 481 and the two rectilinear portions 406.

Regardless of the embodiment, the air gaps 77 and 79 need not necessarily be centred on the walls 26 and 28. They need not necessarily be formed in an inner wall and in an outer wall of the ferromagnetic element 23, 223 or 423.

Any feature described above for one embodiment or variant is applicable to the other embodiments and variants described above, provided that it is technically possible.

1. An electrical current measurement module for measuring an electrical current passing through an electrical conductor the measurement module comprising:
two identical rectilinear portions of a main coil of electrically conductive wire, each rectilinear portion including a support comprising a body of linear shape and at least one end,
at least one ferromagnetic element,
characterized in that the measurement module is configured to adopt
a closed configuration in which the at least one ferromagnetic element covers the distinct end of each rectilinear portion of the main coil, and
an open configuration in which the at least one ferromagnetic element is separated from the rectilinear portions.

2. The measurement module according to claim 1, wherein the rectilinear portions of the main coil have identical and constant linear densities of electrically conductive wire over their respective length.

3. The measurement module according to claim 1, wherein, for each rectilinear portion, a beginning of the coil of conductive wire and an end of the coil of conductive wire are positioned at the at least one end.

4. The measurement module according to claim 1, wherein, for each rectilinear portion, a maximum transverse dimension of the at least one end is greater than a maximum transverse dimension of the body.

5. The measurement module according to claim 1, wherein the rectilinear portions are made of printed circuit.

6. The measurement module according to claim 1, wherein the at least one ferromagnetic element comprises two housings shaped to fit the ends so that the ends are housed and centred in the housings in the closed configuration.

7. The measurement module according to claim 6, wherein each of the housings is formed by an end portion of the at least one ferromagnetic element which defines at least one air gap passing through a peripheral wall of the housing to the outside of the housing.

8. The measurement module according to claim 1, wherein the at least one ferromagnetic element is made by folding a plate of ferromagnetic material.

9. The measurement module according to claim 8, wherein the plate comprises a central rectilinear portion and two pairs of tabs extending at ends of the rectilinear portion, each pair of tabs forming one of the housings once the plate is folded.

10. The measurement module according to claim 1, comprising at least one additional ferromagnetic-element plate fastened to the at least one ferromagnetic element.

11. The measurement module according to claim 1, wherein the at least one ferromagnetic element is made by machining.

12. The measurement module according to claim 1, wherein the at least one ferromagnetic element is made of a ferromagnetic material having a relative magnetic permeability greater than or equal to 10,000.

13. The measurement module according to claim 1, comprising two ferromagnetic elements.

14. The measurement module according to claim 1, comprising a single ferromagnetic element.

15. A method of measuring an electrical current passing through an electrical conductor using an electrical current measurement module, the method comprising:
providing two identical rectilinear portions of a main coil of electrically conductive wire, each rectilinear portion including a support comprising a body of linear shape and at least one end;
providing at least one ferromagnetic element;
arranging the measurement module in a closed configuration by covering the distinct end of each rectilinear portion of the main coil with the at least one ferromagnetic element;
positioning the electrical conductor within the measurement module; and
measuring the electrical current passing through the electrical conductor.

16. The method of claim 15, further comprising arranging the measurement module in an open configuration by separating the at least one ferromagnetic element from the rectilinear portions prior to positioning the electrical conductor within the measurement module.

17. The method of claim 15, wherein the rectilinear portions of the main coil have identical and constant linear densities of electrically conductive wire over their respective length.

18. The method of claim 15, wherein, for each rectilinear portion, a beginning of the coil of conductive wire and an end of the coil of conductive wire are positioned at the at least one end.

19. The method of claim 15, wherein the at least one ferromagnetic element comprises two housings shaped to fit the ends so that the ends are housed and centered in the housings in the closed configuration, and wherein each of the housings is formed by an end portion of the at least one ferromagnetic element which defines at least one air gap passing through a peripheral wall of the housing to the outside of the housing.

20. The method of claim 19, wherein the at least one ferromagnetic element is made by folding a plate of ferromagnetic material, the plate comprising a central rectilinear portion and two pairs of tabs extending at ends of the rectilinear portion, each pair of tabs forming one of the housings once the plate is folded.
